(19) United States
(12) Patent Application Publication
(10) Pub. No.: US 2025/0294888 A1
(43) Pub. Date: Sep. 18, 2025

(54) STACKED MEMORY PHYSICAL LAYER (PHY) FLOORPLAN

(71) Applicant: QUALCOMM Incorporated, San Diego, CA (US)

(72) Inventors: Srivatsan THIRUVENGADAM, Carlsbad, CA (US); Vivek MOHAN, San Diego, CA (US)

(21) Appl. No.: 18/608,440

(22) Filed: Mar. 18, 2024

(51) Int. Cl. H01L 27/02; H01L 23/00; H01L 23/31; H01L 25/10; H01L 25/18; H10B 80/00

(52) U.S. Cl. CPC H10D 89/10; H01L 23/3128; H01L 23/3135; H01L 24/16; H01L 25/105; H01L 25/18; H10B 80/00; H01L 2224/16227; H01L 2924/1431; H01L 2924/14361

(57) ABSTRACT

A die includes a first set of physical layer (PHY) blocks arranged in a first column, wherein the first column extends along a side of the die. The die also includes a second set of PHY blocks arranged in a second column adjacent to the first column. The first set of PHY blocks include a first PHY block, the second set of PHY blocks include a second PHY block, and the first PHY block and the second PHY block share one or more clock resources.

### BACKGROUND

### Field

Aspects of the present disclosure relate generally to memory interfaces, and more particularly, to memory physical layer (PHY) floorplans.

### Background

A system may include one or more processors and one or more memory devices for storing data and/or instructions for the one or more processors. For example, the one or more memory devices may be implemented with double data rate (DDR) memory, which increases data transfer rates by transferring data on both the rising and falling edges of a clock signal. The one or more processors may access the one or more memory devices using a memory controller, which interfaces with the one or more memory devices via a memory interface.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a system including a die. The die includes a first set of physical layer (PHY) blocks arranged in a first column, wherein the first column extends along a side of the die. The die also includes a second set of PHY blocks arranged in a second column adjacent to the first column. The first set of PHY blocks include a first PHY block, the second set of PHY blocks include a second PHY block, and the first PHY block and the second PHY block share one or more clock resources.

A second aspect relates to a system including a die. The die includes physical layer (PHY) blocks arranged in at least two columns, wherein a first column of the at least two columns extends along a side of the die, a second column of the at least two columns is adjacent to the first column, the PHY blocks include a first PHY block in the first column and a second PHY block in the second column, and the first PHY block and the second PHY block share one or more clock resources.

### BRIEF DESCRIPTION OF THE DRAWINGS

FIG. 1 shows an example of a memory device and a die including a processor, a memory controller, and a memory interface according to certain aspects of the present disclosure.

FIG. 2 shows a side view of the die in a package according to certain aspects of the present disclosure.

FIG. 3 shows an exemplary layout of a memory interface including physical layer (PHY) blocks according to certain aspects of the present disclosure.

FIG. 4A shows a block diagram of an exemplary PHY block according to certain aspects of the present disclosure.

FIG. 4B shows an exemplary layout of bumps for the PHY block of FIG. 4A according to certain aspects of the present disclosure.

FIG. 5 shows an exemplary layout of a memory interface including physical layer (PHY) blocks arranged in two columns along a first side of a die and PHY blocks arranged in two columns along a second side of the die according to certain aspects of the present disclosure.

FIG. 6 shows an example in which the number of PHY blocks on a die is increased by adding additional columns of PHY blocks according to certain aspects of the present disclosure.

FIG. 7A shows a block diagram of a first PHY block and a second PHY block located in adjacent columns according to certain aspects of the present disclosure.

FIG. 7B shows an exemplary layout of bumps for the first PHY block and the second PHY block of FIG. 7A according to certain aspects of the present disclosure.

FIG. 8A shows an example in which the first PHY block and the second PHY block of

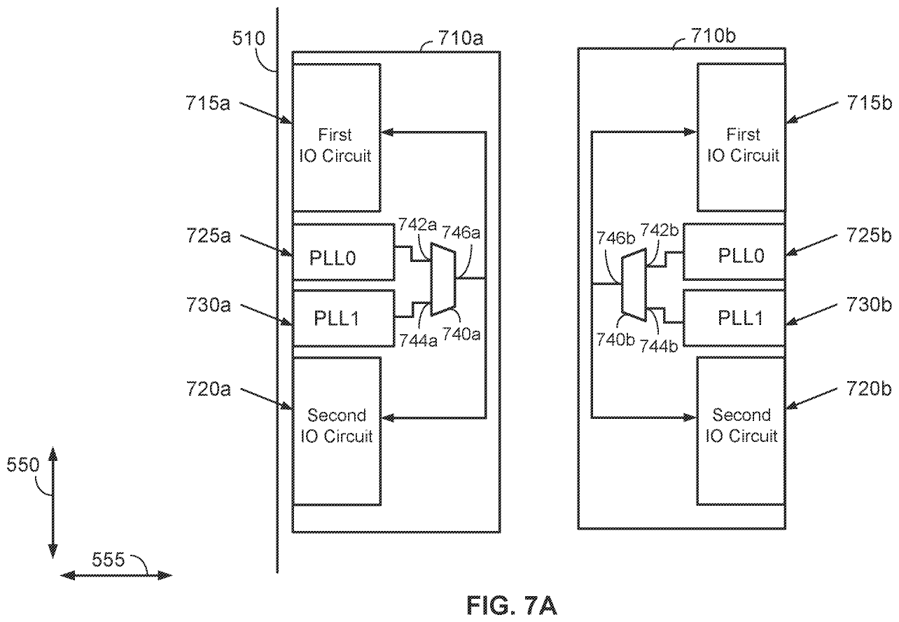

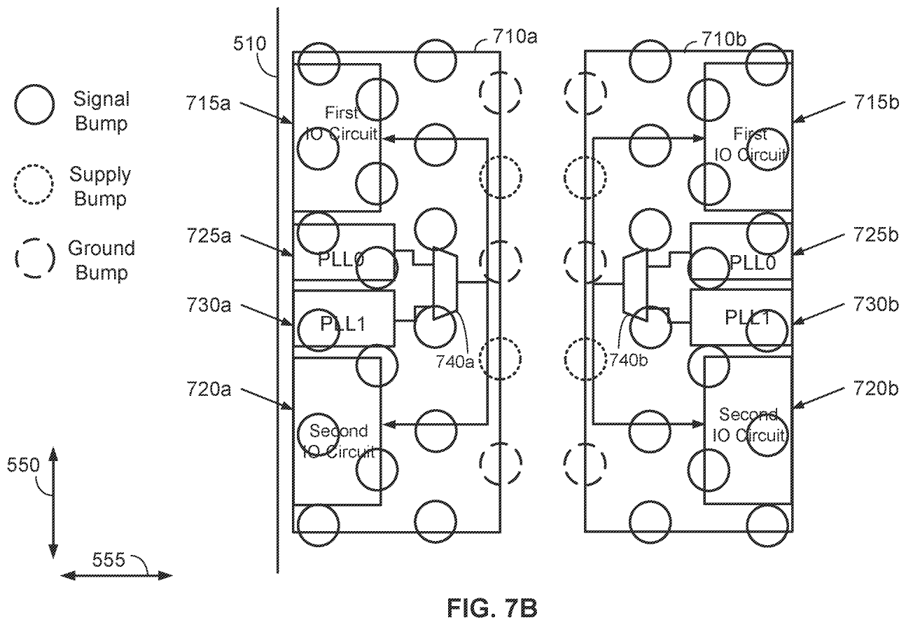

FIG. 7A are placed closer together according to certain aspects of the present disclosure.

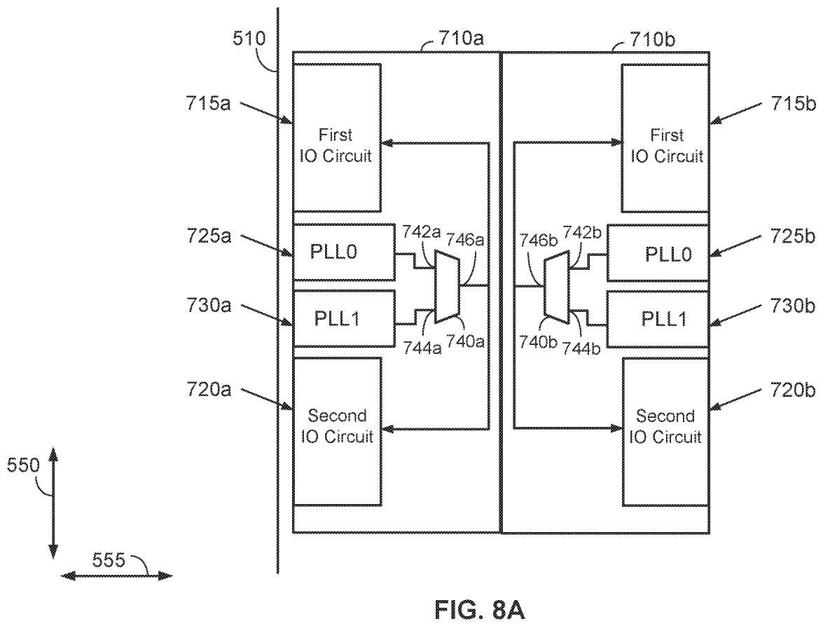

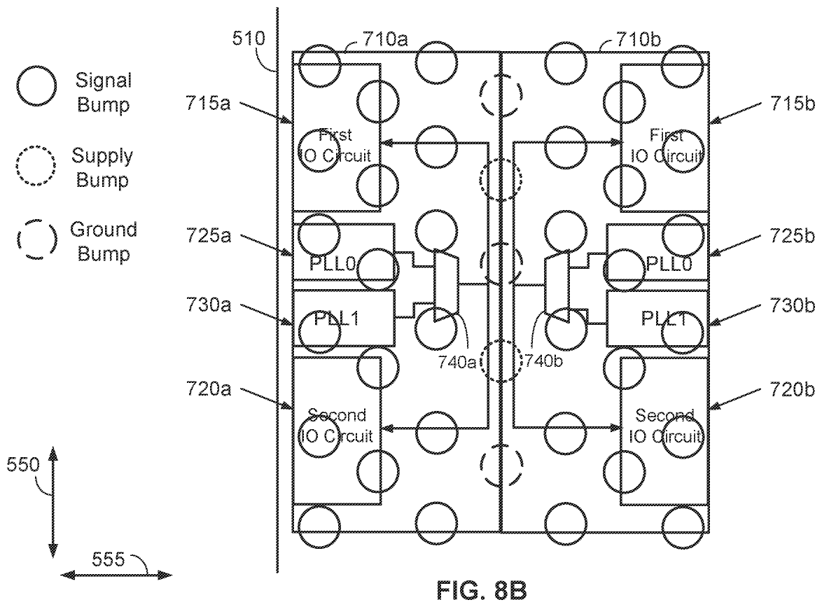

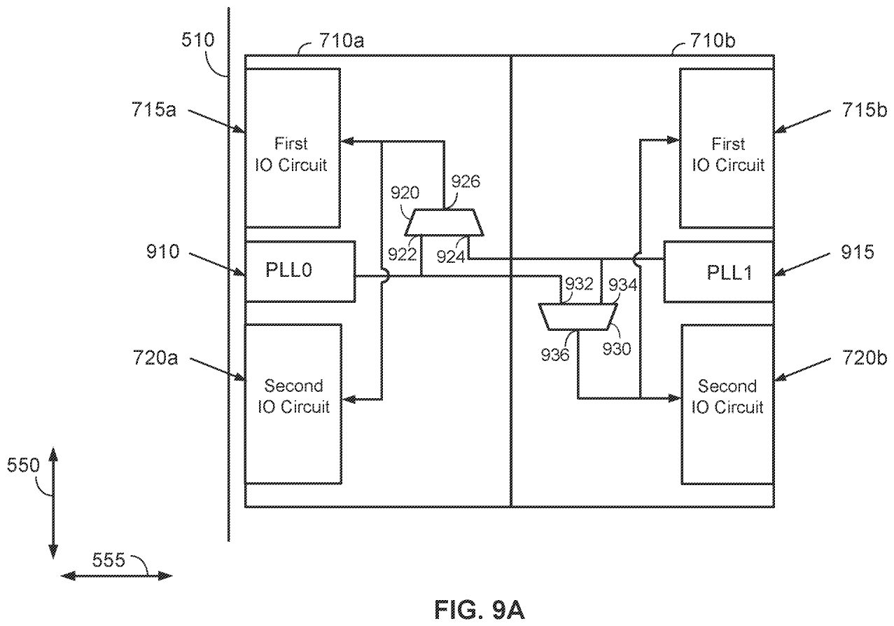

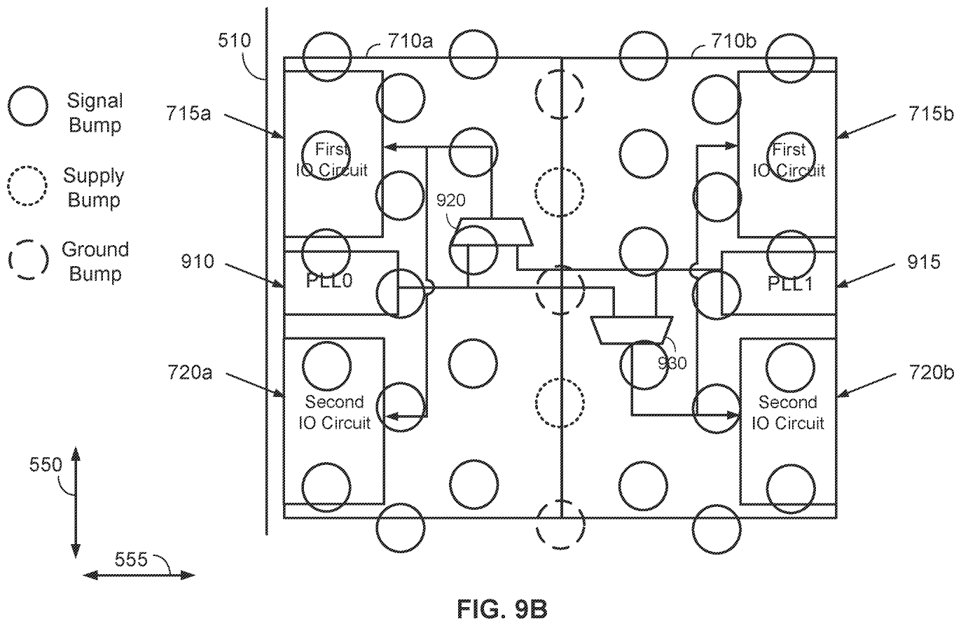

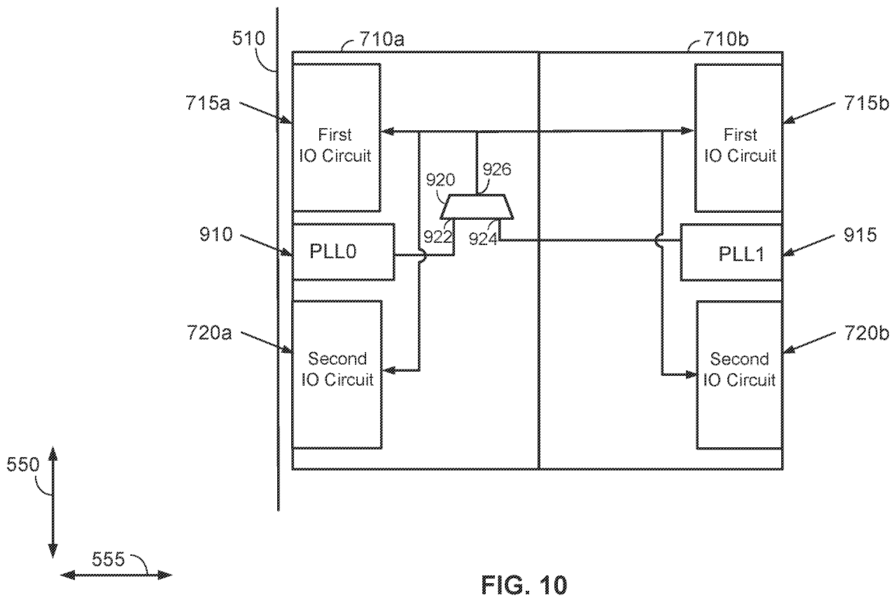

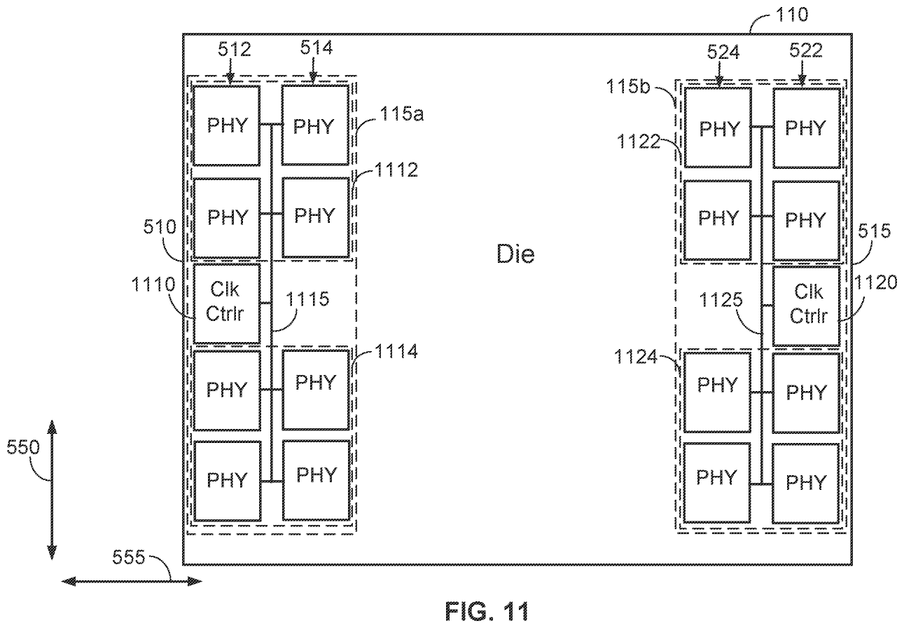

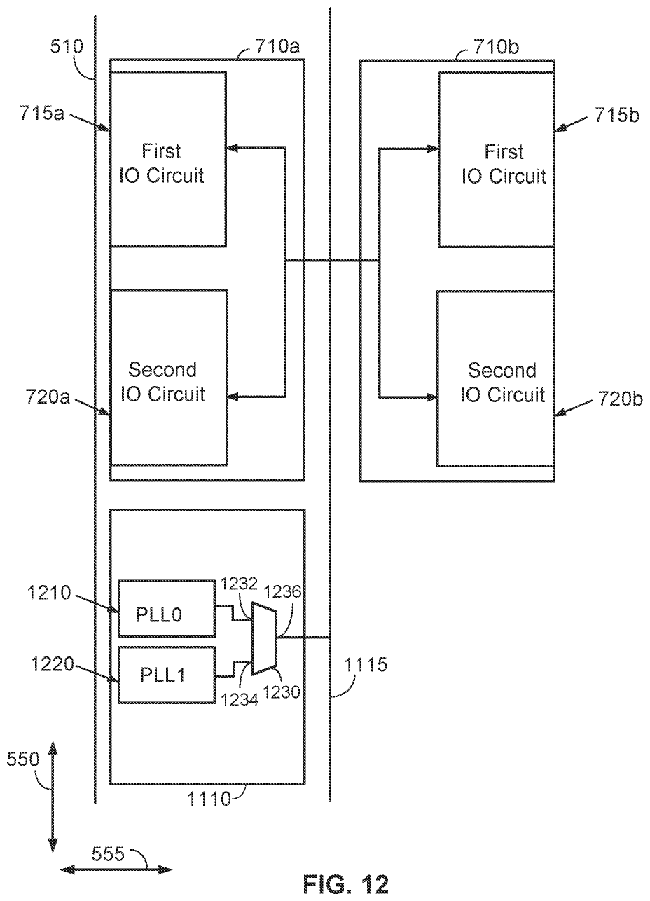

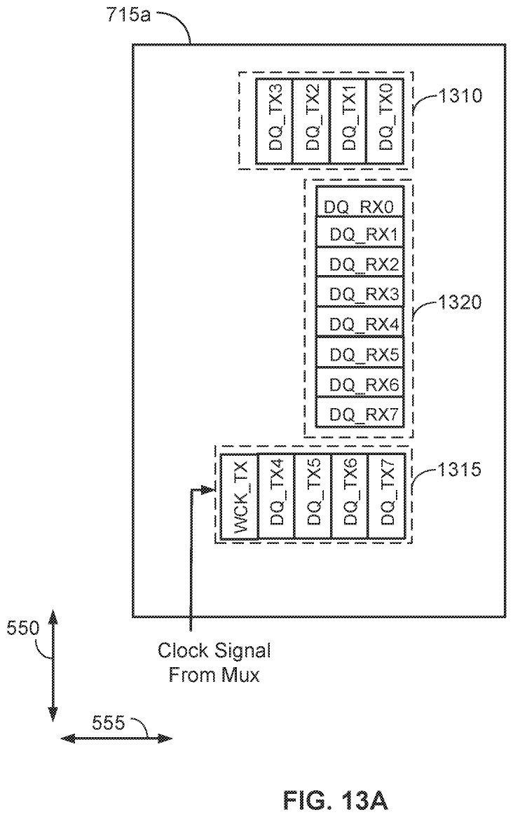

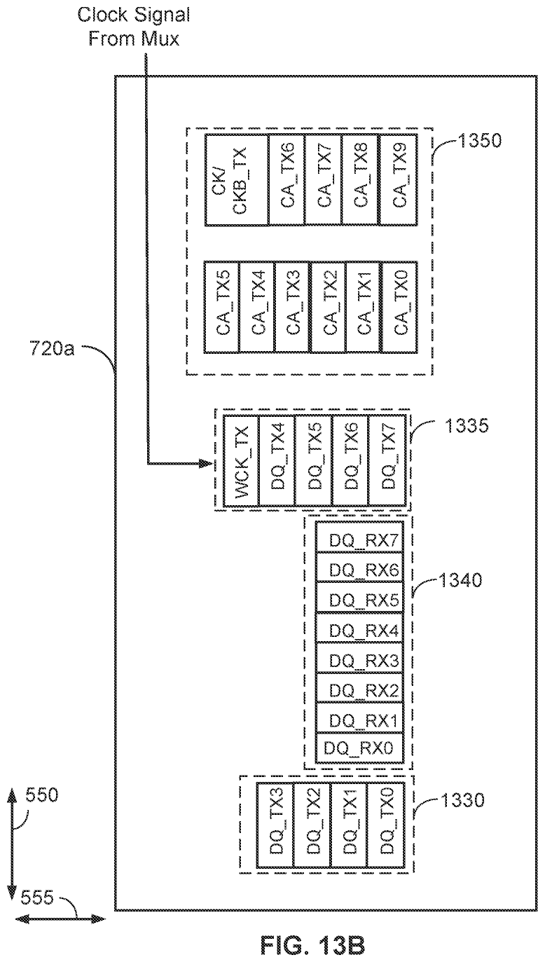

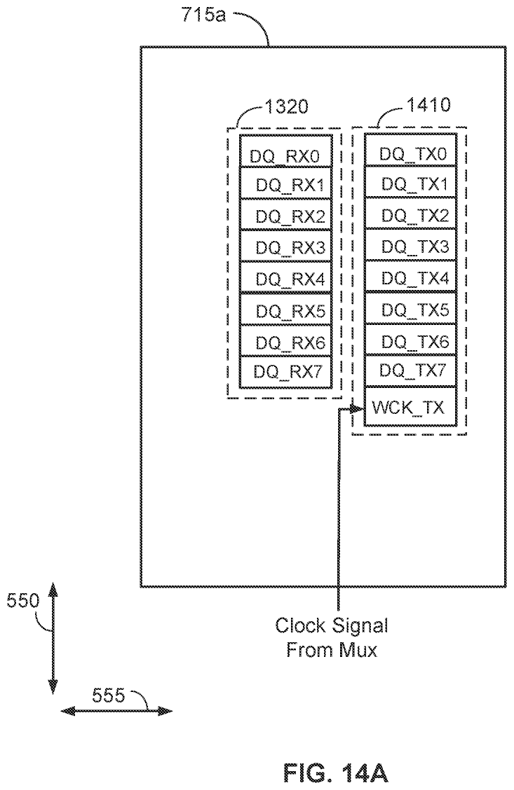

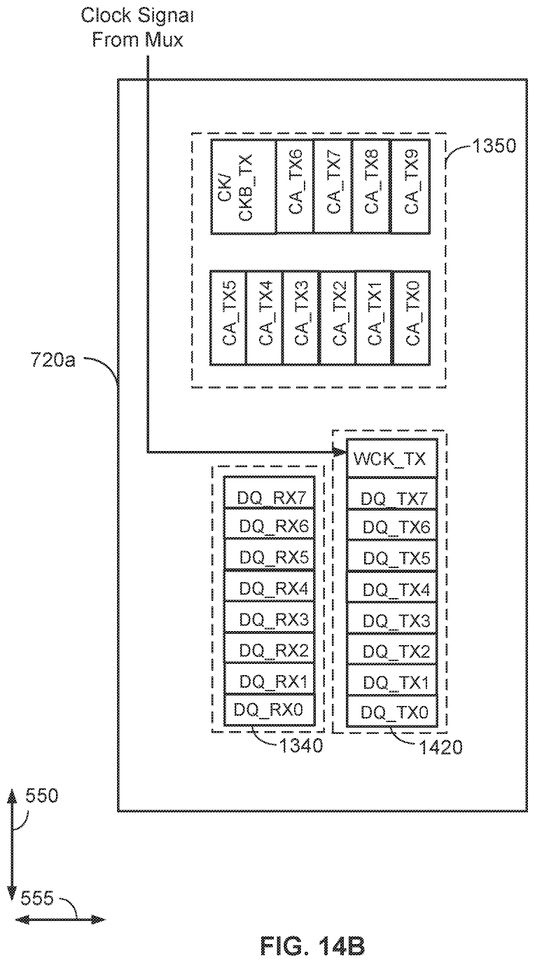

FIG. 8B shows an exemplary layout of bumps for the first PHY block and the second PHY block of FIG. 8A according to certain aspects of the present disclosure.

FIG. 9A shows an example in which a first PHY block and a second PHY block share phase locked loops (PLLs) according to certain aspects of the present disclosure.

FIG. 9B shows an exemplary layout of bumps for the first PHY block and the second PHY block of FIG. 9A according to certain aspects of the present disclosure.

FIG. 10 shows an example in which a first PHY block and a second PHY block share PLLs and a multiplexer according to certain aspects of the present disclosure.

FIG. 11 shows an example in which PHY blocks in a first portion of a memory interface share clock resources and PHY blocks in a second portion of the memory interface share clock resources according to certain aspects of the present disclosure.

FIG. 12 shows an exemplary implementation of a clock circuit, a first PHY block, and a second PHY block according to certain aspects of the present disclosure.

FIG. 13A shows an example of a first input-output (IO) circuit according to certain aspects of the present disclosure.

FIG. 13B shows an example of a second IO circuit according to certain aspects of the present disclosure.

FIG. 14A shows another example of a first input-output (IO) circuit according to certain aspects of the present disclosure.

FIG. 14B shows another example of a second IO circuit according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

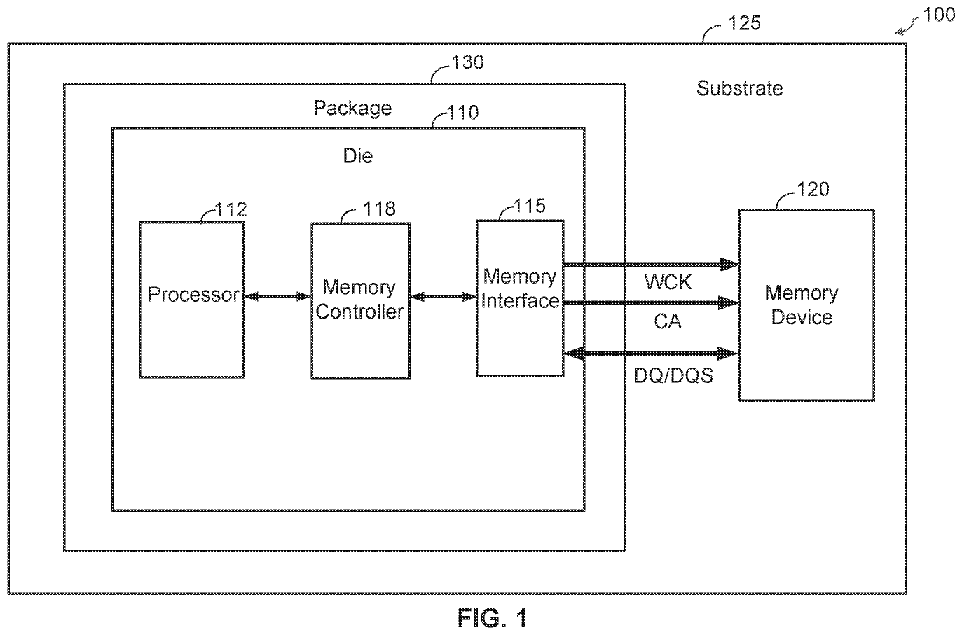

FIG. 1 shows an example of a system 100 in which aspects of the present disclosure may be used. The system 100 may be included in a smartphone, a laptop computer, a tablet, an Internet of things (IOT) device, or the like.

In this example, the system 100 includes a die 110 (i.e., a chip) and an external memory device 120. The die 110 includes a processor 112, a memory controller 118, and a memory interface 115. The memory device 120 may be used to store data and/or instructions for the processor 112. The processor 112 is coupled to the memory controller 118, which is configured to provide the processor 112 with access to the memory device 120, as discussed further below. The processor 112 may include a central processing unit (CPU), a modem processor, a graphics processor, a processor core, etc. Although one processor 112 is shown in FIG. 1, it is to be appreciated that the die 110 may include multiple processors (e.g., multiple processor cores) that use the memory controller 118 to access the memory device 120.

The memory controller 118 is coupled to the memory interface 115, which interfaces the memory controller 118 with the memory device 120, as discussed further below. The memory interface 115 is coupled to the memory device 120 via multiple links configured to transport, for example, data (DQ), data strobe signals (DQS), command-address (CA) signals, write clock signals (WCK), etc.

The memory device 120 may include a double data rate (DDR) memory such as low-power DDR (LPDDR) memory to conserve power. In this example, the double data rate (DDR) increases the data transfer rate of the memory device 120 by transferring data on both the rising and falling edges of a clock signal. For the example of DDR, the memory interface 115 may also be referred to as a DDR interface.

As discussed above, the memory controller 118 provides the processor 112 with access to the memory device 120. For example, the memory controller 118 may read data from the memory device 120 via the memory interface 115 and forward the read data to the processor 112. The memory controller 118 may also receive data from the processor 112 and write the data to the memory device 120 via the memory interface 115.

For example, to read data from the memory device 120, the processor 112 may send a read request to the memory controller 118 requesting data from the memory device 120. In response to the read request, the memory controller 118 sends a read command and the address of the requested data to the memory device 120 via the memory interface 115. The memory device 120 receives the read command and the address, and reads the requested data from memory (e.g., an array of memory cells) at the address. The memory device 120 may then transmit one or more data signals including the read data to the memory interface 115. The memory device 120 may also transmit a data strobe signal.

The memory interface 115 receives the one or more data signals and the data strobe signal from the memory device 120. The memory interface 115 uses the data strobe signal to capture the read data from the one or more data signals and sends the captured read data to the memory controller 118, which forwards the read data to the processor 112.

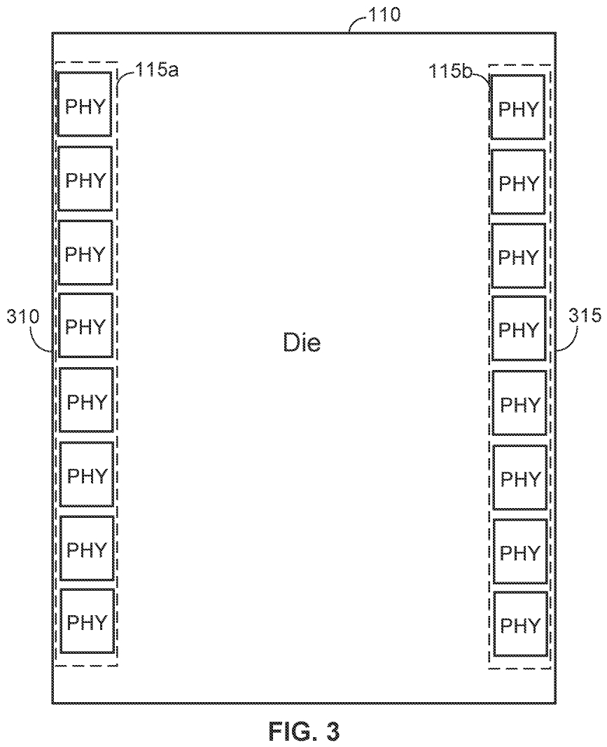

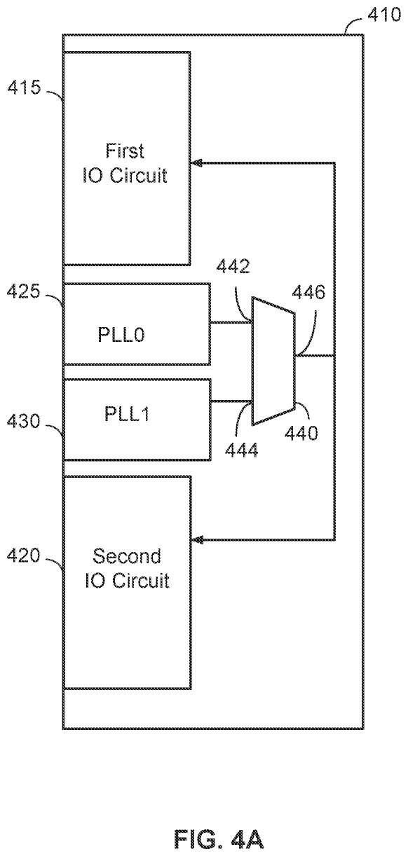

In the example in FIG. 1, the processor 112, the memory controller 118, and the memory interface 115 are integrated on the die 110 (i.e., chip) and the memory device 120 is external to the die 110. The memory interface 115 includes multiple physical layer (PHY) blocks (also referred to as PHYs for short or PHY interfaces). An example of the PHYS is discussed below with reference to FIG. 3. Although the memory interface 115 is shown on one side of the die 110 in FIG. 1 for simplicity, it is to be appreciated that the memory interface 115 may be located on two or more sides of the die 110, as discussed further below. Also, in some implementations, the memory device 120 may be located above or below the die 110 (e.g., in a package on package (POP) configuration).

In this example, the die 110 (i.e., chip) is packaged in a package 130. The package 130 and the memory device 120 are mounted on a substrate 125 (e.g., a printed circuit board (PCB)), in which the memory interface 115 on the die 110 is coupled to the memory device 120 via metal traces on the substrate 125 and/or embedded in the substrate 125 (e.g., PCB). Although one memory device 120 is shown in FIG. 1, it is to be appreciated that the memory interface 115 on the die 110 may be coupled to multiple memory devices mounted on the substrate 125.

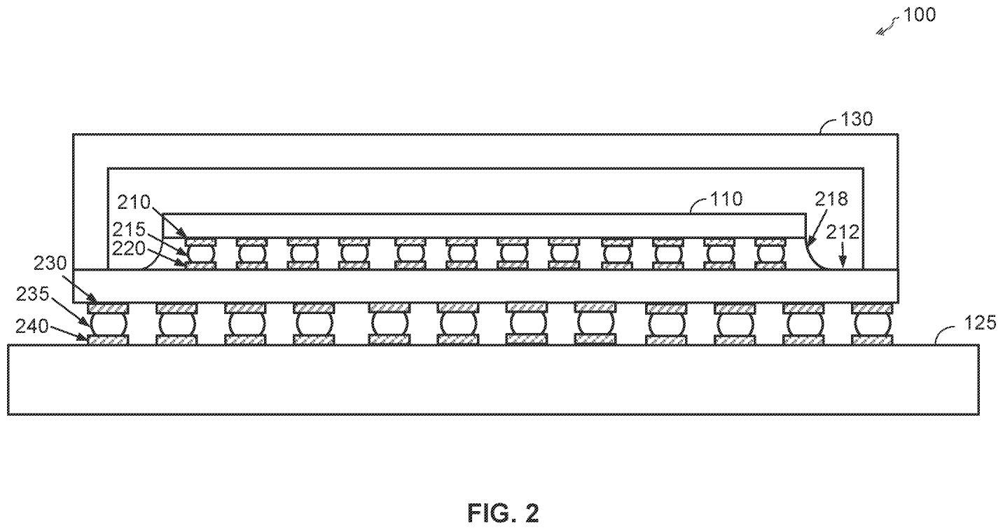

FIG. 2 shows an example of a side view of the die 110, the package 130, and the substrate 125 according to certain aspects. In this example, the die 110 resides within the package 130. The die 110 is flip-chip mounted onto a surface 212 of the package 130 with an array of bumps 215 (e.g., solder bumps) coupling pins 210 on the die 110 to package pins 220 on the package 130 to provide electrical connections to the die 110. The pins 210 may also referred to as pads or another term. The space between the die 110 and the surface 212 of the package 130 may be filled with an underfill 218 (e.g., a resin). It is to be appreciated that the pins 210 and 220 and the bumps 215 are not necessarily drawn to scale in FIG. 2.

FIG. 2 also shows an example of the package 130 mounted on the substrate 125 (e.g., PCB) with an array of solder balls 235 (also referred to as a ball grid array (BGA)) coupling pins 230 on the package 130 to pads 240 on the substrate 125. The pins 230 may be coupled to the package pins 220 by metal routing (not shown) in the package 130. The pads 240 on the substrate 125 may be coupled to the memory device 120 (shown in FIG. 1) via metal traces (not shown) on the substrate 125 and/or embedded in the substrate 125.

FIG. 3 shows an exemplary layout (i.e., floorplan) of the memory interface 115 on the die 110. In this example, the memory interface 115 includes a first portion 115a that extends along a first side 310 of the die 110 and a second portion 115b that extends along a second side 315 of the die 110. In the example shown in FIG. 3, the first portion 115a of the memory interface 115 includes eight PHYs placed along the first side 310 of the die 110 and the second portion 115b of the memory interface 115 includes eight PHYs placed along the second side 315 of the die 110. Each of the PHYs in FIG. 3 is shown as a block labeled “PHY.” As such, the PHY may also be referred to as a PHY block. In this example, each PHY may support one channel capable of transmitting two bytes (i.e., 16 data bits in parallel) to the memory device 120 and receiving two bytes in parallel from the memory device 120. However, it is to be appreciated that the PHYs are not limited to this example. For case of illustration, the processor 112 and the memory controller 118 are not shown in FIG. 3. The processor 112 and the memory controller 118 may be located between the first portion 115a and the second portion 115b of the memory interface 115.

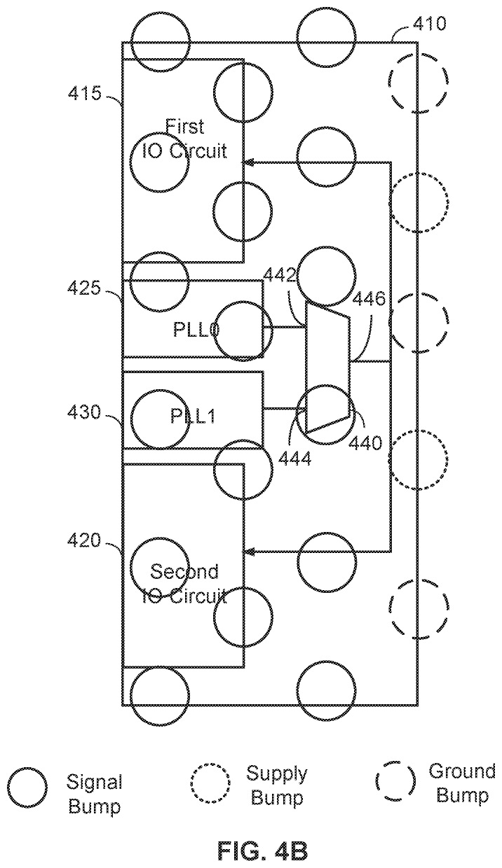

FIG. 4A shows an exemplary block diagram of a PHY 410 according to certain aspects. The PHY 410 may be used to implement each of the PHYs shown in FIG. 3 (i.e., each of the PHYs in FIG. 3 may be a separate instance of the PHY 410).

In this example, the PHY 410 includes a first input-output (IO) circuit 415 and a second IO circuit 420. The first IO circuit 415 may include transmitters (i.e., drivers) for transmitting a byte (e.g., eight bits in parallel) from the memory controller 118 to the memory device 120 and receivers for receiving a byte (e.g., eight bits in parallel) from the memory device 120. The second IO circuit 420 may include transmitters (i.e., drivers) for transmitting a byte (e.g., eight bits in parallel) from the memory controller 118 to the memory device 120 and receivers for receiving a byte (e.g., eight bits in parallel) from the memory device 120. Together, the first and second IO circuits 415 and 420 allow the PHY 410 to transmit two bytes (e.g., 16 bits in parallel) to the memory device 120 and receive two bytes (e.g., 16 bits in parallel) from the memory device 120 in this example.

The PHY 410 also includes a first phase locked loop (PLL) 425, a second PLL 430, and a multiplexer 440. The first PLL 425 is configured to generate a first clock signal and the second PLL 430 is configured to generate a second clock signal. The multiplexer 440 has a first input 442 coupled to the first PLL 425 to receive the first clock signal, a second input 444 coupled to the second PLL 430 to receive the second clock signal, and an output 446 coupled to the first and second IO circuits 415 and 420. The multiplexer 440 is configured to select the first clock signal or the second clock signal (e.g., based on a select signal from the memory controller 118 or another circuit), and output the selected clock signal to the first and second IO circuits 415 and 420.

The first and second IO circuits 415 and 420 may use the selected clock signal to time the transmission of data bits, command bits, and/or address bits to the memory device 120. The first and second IO circuits 415 and 420 may also transmit the selected clock signal and/or transmit a clock signal based on the selected clock signal to the memory device 120 (e.g., to time the capture of data bits, command bits, and/or address bits at the memory device 120). The first clock signal from the first PLL 425 and the second clock signal from the second PLL 430 may have different frequencies. This allows the PHY 410 to quicky switch between clock frequencies by switching between the first clock signal from the first PLL 425 and the second clock signal from the second PLL 430 using the multiplexer 440.

FIG. 4B shows as exemplary layout of bumps (shown as circles) coupling the PHY 410 to package pins (e.g., package pins 220). In this example, the bumps include bumps for signaling (e.g., transmitting data bits, command bits and/or address bits and receiving data bits and/or data strobe signals), bumps for providing the PHY 410 with a supply voltage, and bumps for providing a ground connection for the PHY 410.

Returning to FIG. 3, FIG. 3 shows an example of a layout (i.e., floorplan) in which the PHYs are arranged in a single column on each of the first and second sides 310 and 315 (i.e., edges) of the die 110. In the example shown in FIG. 3, eight of the PHYs are arranged in a single column on the first side 310 of the die 110, and eight of the PHYs are arranged in a single column on the second side 315 of the die 110.

A problem with the layout approach illustrated in FIG. 3 is that this layout approach may significantly increase the area of the die and/or skew the aspect ratio of the die 110 as the number of PHYs increases (e.g., to accommodate more channels for artificial intelligence (AI) applications or high bandwidth applications). For example, using the example in FIG. 3, doubling the number of channels (and hence doubling the number of PHYs) may require doubling the height of the die 110 to accommodate the additional PHYs along the first side 310 and the second side 315 of the die 110. In this example, the larger die 110 requires the use of a larger package size, which can lead to larger bump sizes and larger pitches between the bumps (which can lead to die wastage due to bump overhang). Also, the layout approach illustrated in FIG. 3 may lead to the loss of pin-to-pin compatibility when the memory bandwidth (e.g., DDR bandwidth) is lowered.

To address the above, aspects of the present disclosure provide a PHY floorplan (i.e., layout) in which at least two columns of PHYs are arranged along one side (i.e., edge) of the die 110, as discussed further below.

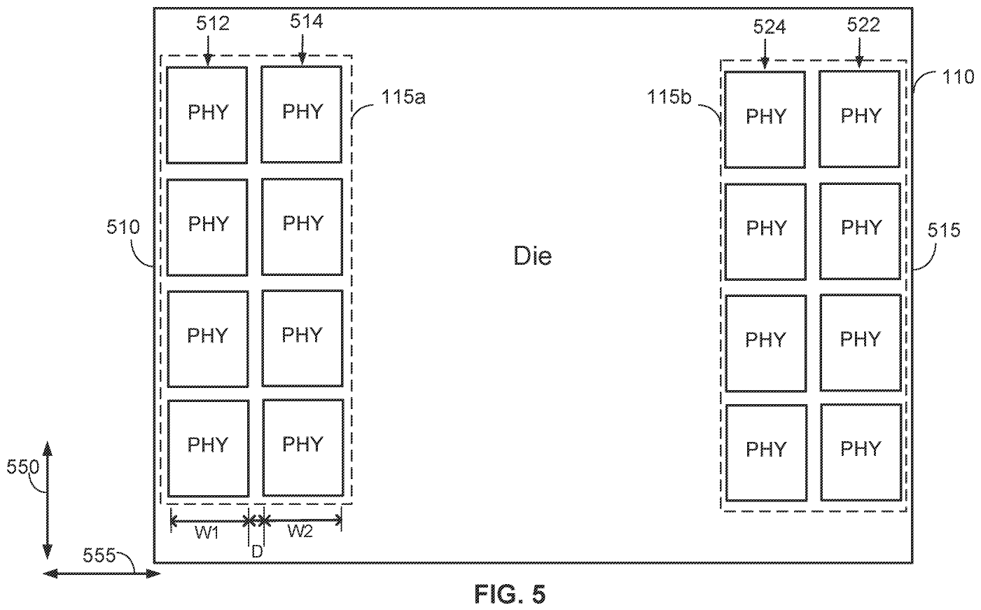

FIG. 5 shows an exemplary layout (i.e., floorplan) of the memory interface 115 on the die 110 according to certain aspects. In this example, the memory interface 115 includes a first portion 115a that extends along a first side 510 of the die 110 and a second portion 115b that extends along a second side 515 of the die 110. In the example in FIG. 5, the sides 510 and 515 (i.e., edges) of the die 110 are opposite sides (i.e., opposing sides) of the die 110 with each of the sides 510 and 515 extending in the direction 550 (e.g., vertical direction). However, it is to be appreciated that the present disclosure is not limited to this example.

The first portion 115a of the memory interface 115 includes PHYs arranged in two columns along the first side 510 of the die 110. The two columns include a first column 512 including a first set of PHYs and a second column 514 including a second set of PHYs. In the example shown in FIG. 5, the first set of PHYs in the first column 512 includes four PHYs and the second set of PHYs in the second column 514 includes four PHYs. However, it is to be appreciated that the columns 512 and 514 are not limited to this example, and that each of the columns 512 and 514 may have a different number of PHYs than shown in the example in FIG. 5. Each of the PHYs in FIG. 5 is shown as a block labeled “PHY.” In this example, each of the columns 512 and 514 extends in the direction 550 (e.g., vertical direction), and the columns 512 and 514 are arranged side by side in the direction 555 (e.g., horizontal direction), which is perpendicular to the direction 550. It is to be appreciated that PHYs arranged in a column may also be described as being arranged in a row depending on the orientation in which the die 110 is viewed. For example, if the die 110 shown in FIG. 5 is rotated 90 degrees, then the columns 512 and 514 may be referred to as rows.

In this example, each of the columns 512 and 514 extends in the direction 550. The first column 512 has a first width (labeled “W1”) in the direction 555, and the second column 514 has a second width (labeled “W2”) in the direction 555, where W1 and W2 may be equal (i.e., the columns 512 and 514 have the same width) or different. In this example, the distance (labeled “D”) between the first column 512 and the second column 514 in the direction 555 is less than the width of each of the columns 512 and 514.

The second portion 115b of the memory interface 115 includes PHYs arranged in two columns along the second side 515 of the die 110. The two columns include a third column 522 including a third set of PHYs and a fourth column 524 including a fourth set of PHYs. In the example shown in FIG. 5, the third set of PHYs in the third column 522 includes four PHYs and the fourth set of PHYs in the fourth column 524 includes four PHYs. However, it is to be appreciated that the columns 522 and 524 are not limited to this example, and that each of the columns 522 and 524 may have a different number of PHYs than shown in the example in FIG. 5. Each of the PHYs in FIG. 5 is shown as a block labeled “PHY.” In this example, each of the columns 522 and 524 extends in the direction 550 (e.g., vertical direction), and the columns 522 and 524 are arranged side by side in the direction 555 (e.g., horizontal direction).

Because of the way the columns 512 and 514, or 524 and 522, are arranged, the exemplary PHY floorplan shown may also referred to as a stacked PHY floorplan. As used herein, PHYs may be stacked when the PHYs are arranged in an N×M array where N is an integer greater than one and M is an integer greater than one. N may correspond to the direction 550 and M may correspond to the direction 555. For example, the PHYs in the columns 512 and 514 are arranged in a 4×2 array in the example shown in FIG. 5. However, it is to be appreciated that the columns 512 and 514 are not limited to this example.

The exemplary layout (i.e., floorplan) shown in FIG. 5 allows the height of the die 110 to be reduced (e.g., by 50 percent) for a given number of PHYs compared with the layout shown in FIG. 3. This is because the layout shown in FIG. 3 arranges the PHYs in a single column on each of the sides 310 and 315 of the die 110 while the exemplary layout shown in FIG. 5 arranges the PHYs in two columns on each of the sides 510 and 515.

In this example, each PHY may support one channel capable of transmitting two bytes (i.e., 16 data bits in parallel) to the memory device 120 and receiving two bytes in parallel from the memory device 120. However, it is to be appreciated that the PHYs are not limited to this example. In this example, the processor 112 and the memory controller 118 (not shown in FIG. 5) may be located between the first portion 115a and the second portion 115b of the memory interface 115 on the die 110.

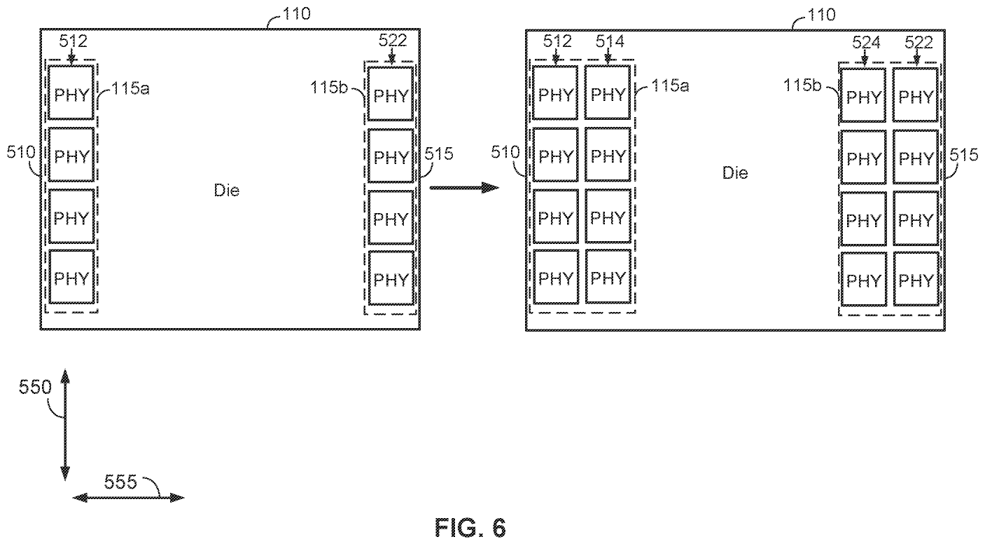

In certain aspects, the exemplary layout approach illustrated in FIG. 5 may be used to increase the number of PHYs (e.g., to support more channels or a larger bandwidth) without significantly increasing the area of the die 110 or significantly skewing the aspect ratio (e.g., height-to-width ratio) of the die 110. In this regard, FIG. 6 shows an example in which the number of PHYs on the die 110 is increased from eight PHYs (shown on the left side of FIGS. 6) to 16 PHYs (shown on the right side of FIG. 6). In the example shown in FIG. 6, the height of the die 110 in the direction 550 is unchanged. This may allow the die 110 to maintain pin-to-pin compatibility (e.g., with the package 130) and reuse of the same substrate 125 (e.g., PCB) and/or package 130. In the example in FIG. 6, the width of the die 110 in the direction 555 may be slightly increased to accommodate the additional column of PHYs on each side 510 and 515 of the die 110.

FIG. 7A shows an exemplary block diagram of a first PHY 710a and a second PHY 710b according to certain aspects. The first PHY 710a and the second PHY 710b are arranged side by side in the direction 555 (e.g., horizonal direction). The first PHY 710a and the second PHY 710b may be used to implement each pair of side-by-side PHYs shown in FIGS. 5 and 6, in which the first PHY 710a and the second PHY 710b are located in two adjacent columns (e.g., the first PHY 710a is located in the column 512 adjacent to the first side 510 of the die 110 and the second PHY 710b is located in the column 514 adjacent to the column 512 shown in FIG. 5). As used herein, two columns are adjacent when the distance between the two columns is less than the width of each of the columns. For example, in the example in FIG. 5, the columns 512 and 514 are adjacent since the distance between the columns 512 and 514 (labeled “D”) is less the width of each of the first column 512 and the second column 514 (labeled “W1” and “W2” respectively).

In this example, the first PHY 710a includes a first IO circuit 715a and a second IO circuit 720a. The first IO circuit 715a may include transmitters (i.e., drivers) for transmitting a byte (e.g., eight bits in parallel) from the memory controller 118 to the memory device 120 and receivers for receiving a byte (e.g., eight bits in parallel) from the memory device 120. The second IO circuit 720a may include transmitters (i.e., drivers) for transmitting a byte (e.g., eight bits in parallel) from the memory controller 118 to the memory device 120 and receivers for receiving a byte (e.g., eight bits in parallel) from the memory device 120. Together, the first and second IO circuits 715a and 720a allow the first PHY 710ato transmit two bytes (e.g., 16 bits in parallel) to the memory device 120 and receive two bytes (e.g., 16 bits in parallel) from the memory device 120 in this example. However, it is to be appreciated that the first PHY 710a is not limited to this example.

The first PHY 710a also includes a first PLL 725a, a second PLL 730a, and a multiplexer 740a. The first PLL 725a is configured to generate a first clock signal and the second PLL 730a is configured to generate a second clock signal. The multiplexer 740a has a first input 742a coupled to the first PLL 725a to receive the first clock signal, a second input 744a coupled to the second PLL 730a to receive the second clock signal, and an output 746a coupled to the first and second IO circuits 715a and 720a. The multiplexer 740a is configured to select the first clock signal or the second clock signal (e.g., based on a select signal from the memory controller 118 or another circuit), and output the selected clock signal to the first and second IO circuits 715a and 720a.

The first and second IO circuits 715a and 720a may use the selected clock signal to time the transmission of data bits, command bits, and/or address bits to the memory device 120. The first and second IO circuits 715a and 720a may also transmit the selected clock signal and/or transmit a clock signal based on the selected clock signal to the memory device 120 (e.g., to time the capture of data bits, command bits, and/or address bits at the memory device 120). The first clock signal from the first PLL 725a and the second clock signal from the second PLL 730a may have different frequencies. This allows the first PHY 710a to quicky switch between clock frequencies by switching between the first clock signal from the first PLL 725a and the second clock signal from the second PLL 730a using the multiplexer 740a.

In this example, the second PHY 710b includes a first IO circuit 715b and a second IO circuit 720b. The first IO circuit 715b may include transmitters (i.e., drivers) for transmitting a byte (e.g., eight bits in parallel) to the memory device 120 and receivers for receiving a byte (e.g., eight bits in parallel) from the memory device 120. The second IO circuit 720b may include transmitters (i.e., drivers) for transmitting a byte (e.g., eight bits in parallel) to the memory device 120 and receivers for receiving a byte (e.g., eight bits in parallel) from the memory device 120. Together, the first and second IO circuits 715b and 720b allow the second PHY 710b to transmit two bytes (e.g., 16 bits in parallel) to the memory device 120 and receive two bytes (e.g., 16 bits in parallel) from the memory device 120 in this example. However, it is to be appreciated that the second PHY 710b is not limited to this example.

The second PHY 710b also includes a first PLL 725b, a second PLL 730b, and a multiplexer 740b. The first PLL 725b is configured to generate a first clock signal and the second PLL 730b is configured to generate a second clock signal. The multiplexer 740b has a first input 742b coupled to the first PLL 725b to receive the first clock signal, a second input 744b coupled to the second PLL 730b to receive the second clock signal, and an output 746b coupled to the first and second IO circuits 715b and 720b. The multiplexer 740b is configured to select the first clock signal or the second clock signal (e.g., based on a select signal from the memory controller 118 or another circuit), and output the selected clock signal to the first and second IO circuits 715b and 720b.

The first and second IO circuits 715b and 720b may use the selected clock signal to time the transmission of data bits, command bits, and/or address bits to the memory device 120. The first and second IO circuits 715b and 720b may also transmit the selected clock signal and/or transmit a clock signal based on the selected clock signal to the memory device 120 (e.g., to time the capture of data bits, command bits, and/or address bits at the memory device 120). The first clock signal from the first PLL 725b and the second clock signal from the second PLL 730b may have different frequencies. This allows the second PHY 710b to quicky switch between clock frequencies by switching between the first clock signal from the first PLL 725b and the second clock signal from the second PLL 730b using the multiplexer 740b.

FIG. 7B shows as exemplary layout of bumps (shown as circles) coupling the first PHY 710a and the second PHY 710b to package pins (e.g., package pins 220). In this example, the bumps include bumps for routing signals (e.g., data bits, command bits, and address bits) between the first PHY 710a and the package (e.g., package 130), bumps for providing the first PHY 710a with a supply voltage, and bumps for providing a ground connection for the first PHY 710a. The bumps also include bumps for routing signals (e.g., data bits, command bits, and address bits) between the second PHY 710b and the package (e.g., package 130), bumps for providing the second PHY 710b with a supply voltage, and bumps for providing a ground connection for the second PHY 710b. In FIG. 7B, the bumps are shown as circles, in which the signal bumps are shown with solid lines, the supply bumps are shown with dotted lines, and the ground bumps are shown with dashed lines.

In certain aspects, the distance between the first PHY 710a and the second PHY 710b is equal to or less than a shortest distance (i.e., spacing) between the centers of bumps on the die 110. This helps the PHYs 710a and 710b make efficient use of the bumps by allowing the bumps for the PHYs 710a and 710b to be placed close together and/or allowing the PHYs 710a and 710b to share one or more bumps, as discussed further below.

FIG. 8A shows an exemplary layout in which the first PHY 710a and the second PHY 710b are placed closer together compared with the example shown in FIG. 7A, and FIG. 8B shows as exemplary layout of the bumps (shown as circles) coupling the first PHY 710a and the second PHY 710b to the package pins (e.g., package pins 220). In this example, the supply bumps and the ground bumps are shared by first PHY 710a and the second PHY 710b, which reduces the number of bumps. In the example shown in FIG. 8B, each of the supply bumps overlaps the first PHY 710a and the second PHY 710b and provides the supply voltage to both the first PHY 710a and the second PHY 710b. Each of the ground bumps overlaps the first PHY 710a and the second PHY 710b and provides a ground connection for both the first PHY 710a and the second PHY 710b. As used herein, a supply bump is a bump that provides a supply voltage (e.g., from an external voltage source) and a ground bump is a bump that provides a connection to ground.

In certain aspects, the first PHY 710a and the second PHY 710b share clock resources. As used herein, shared clock resources may include shared clock generation circuits (e.g., shared PLLs), shared clock routing, and/or shared clock switching circuits (e.g., shared multiplexers). In this regard, FIG. 9A shows an exemplary implementation in which the first PHY 710a and the second PHY 710b share PLLs, as discussed further below. In this example, the first PHY 710a includes the first IO circuit 715a and the second IO circuit 720a discussed above, and the second PHY 710b includes the first IO circuit 715b and the second IO circuit 720b discussed above.

In the example shown in FIG. 9A, the first PHY 710a includes a first PLL 910 in place of the first PLL 725a and the second PLL 730a shown in FIGS. 7A and 8A, and the second PHY 710b includes a second PLL 915 in place of the first PLL 725b and the second PLL 730b shown in FIGS. 7A and 8A. The first PLL 910 is configured to generate a first clock signal and the second PLL 915 is configured to generate a second clock signal, which may have a different frequency than the first clock signal. In this example, the first PLL 910 and the second PLL 915 are shared by the first and second PHYs 710a and 710b. This reduces the number of PLLs in the first and second PHYs 710a and 710b from four PLLs (i.e., PLLs 725a, 730a, 725b, and 730b) to two PLLs (i.e., PLLs 910 and 915), which reduces the active power and leakage power associated with the PLLs.

In this example, the first PHY 710a includes a first multiplexer 920. The first multiplexer 920 has a first input 922 coupled to the first PLL 910 to receive the first clock signal, a second input 924 coupled to the second PLL 915 in the second PHY 710b to receive the second clock signal, and an output 926 coupled to the first and second IO circuits 715a and 720a in the first PHY 710a. The first multiplexer 920 is configured to select the first clock signal or the second clock signal (e.g., based on a select signal from the memory controller 118 or another circuit), and output the selected clock signal to the first and second IO circuits 715a and 720a.

As discussed above, the first and second IO circuits 715a and 720a may use the selected clock signal to time the transmission of data bits, command bits, and/or address bits to the memory device 120. The first and second IO circuits 715a and 720a may also transmit the selected clock signal and/or transmit a clock signal based on the selected clock signal to the memory device 120 (e.g., to time the capture of data bits, command bits, and/or address bits at the memory device 120).

In this example, the second PHY 710b includes a second multiplexer 930. The second multiplexer 930 has a first input 932 coupled to the first PLL 910 in the first PHY 710a to receive the first clock signal, a second input 934 coupled to the second PLL 915 to receive the second clock signal, and an output 936 coupled to the first and second IO circuits 715b and 720b in the second PHY 710b. The second multiplexer 930 is configured to select the first clock signal or the second clock signal (e.g., based on a select signal from the memory controller 118 or another circuit), and output the selected clock signal to the first and second IO circuits 715b and 720b.

As discussed above, the first and second IO circuits 715b and 720b may use the selected clock signal to time the transmission of data bits, command bits, and/or address bits to the memory device 120. The first and second IO circuits 715b and 720b may also transmit the selected clock signal and/or transmit a clock signal based on the selected clock signal to the memory device 120 (e.g., to time the capture of data bits, command bits, and/or address bits at the memory device 120).

In certain aspects, the first multiplexer 920 and the second multiplexer 930 may receive the same select signal (e.g., from the memory controller 118 or another circuit). In this example, the first multiplexer 920 and the second multiplexer 930 select the same clock signal for both PHYs 710a and 710b. In another example, the first multiplexer 920 and the second multiplexer 930 may receive separate select signals (e.g., from the memory controller 118 or another circuit). In this example, the first multiplexer 920 and the second multiplexer 930 select the same clock signal or different clock signals depending on the respective select signals.

FIG. 9B shows as exemplary layout of bumps (shown as circles) coupling the first PHY 710a and the second PHY 710b to package pins (e.g., package pins 220). In this example, the bumps include bumps for routing signals (e.g., data bits, command bits, and address bits) between the first PHY 710a and the package 130, and bumps for routing signals (e.g., data bits, command bits, and address bits) between the second PHY 710b and the package 130. In this example, bumps also include supply bumps and the ground bumps shared by first PHY 710a and the second PHY 710b. In the example shown in FIG. 9B, each of the supply bumps overlaps the first PHY 710a and the second PHY 710b and provides the supply voltage to both the first PHY 710a and the second PHY 710b. Each of the ground bumps overlaps the first PHY 710a and the second PHY 710b and provides a ground connection for both the first PHY 710a and the second PHY 710b. However, it is to be appreciated that the present disclosure is not limited to this example. In other implementations, the first PHY 710a and the second PHY 710b may have different supply bumps and/or different ground bumps. In FIG. 9B, the bumps are shown as circles, in which the signal bumps are shown with solid lines, the supply bumps are shown with dotted lines, and the ground bumps are shown with dashed lines.

FIG. 10 shows an example in which the second multiplexer 930 is omitted and the first PHY 710a and the second PHY 710b share the first multiplexer 920. In this example, the output 926 of the first multiplexer 920 is also coupled to the first IO circuit 715b and the second IO circuit 720b of the second PHY 710b. In this example, the same clock signal is selected for both PHYs 710a and 710b since the PHYs 710a and 710b share the first multiplexer 920 in this example. In this example, the layout of the bumps for the first PHY 710a and the second PHY 710b may be the same or similar to the exemplary layout shown in FIG. 9B. Although the first multiplexer 920 is located in the first PHY 710a in the example shown in FIG. 10, it is to be appreciated that the first multiplexer 920 may be located in the second PHY 710b in other implementations.

FIG. 11 shows an example in which the PHYs on each of the sides 510 and 515 of the die 110 share clock resources (e.g., PLLs). The shared clock resources reduce power consumption associated with clock generation in the memory interface 115.

In this example, the first portion 115a of the memory interface 115 includes a first clock circuit 1110 located between PHYs in the column 512. In the example shown in FIG. 11, the first clock circuit 1110 is centrally located in the first portion 115a of the memory interface 115 between a first group of the PHYs 1112 and a second group of the PHYS 1114 in the first portion 115a of the memory interface 115. However, it is to be appreciated that the first clock circuit 1110 is not limited to this example. The first clock circuit 1110 is configured to output a clock signal which is distributed to each of the PHYs in the first portion 115a of the memory interface 115 via exemplary clock routing 1115 shown in FIG. 11. As exemplary implementation of the clock circuit 1110 is discussed below with reference to FIG. 12. Each of the PHYs may use the clock signal provided by the first clock circuit 1110 to time the transmission of respective data bits, command bits, and/or address bits to the memory device 120. Each of the PHYs may also transmit the clock signal provided by the first clock circuit 1110 and/or transmit a clock signal based on the clock signal provided by the first clock circuit 1110 to the memory device 120.

In this example, the second portion 115b of the memory interface 115 includes a second clock circuit 1120 located between PHYs in the column 522. In the example shown in FIG. 11, the second clock circuit 1120 is centrally located in the second portion 115b of the memory interface 115 between a first group of the PHYs 1122 and a second group of the PHYs 1124 in the second portion 115b of the memory interface 115. However, it is to be appreciated that the second clock circuit 1120 is not limited to this example. The second clock circuit 1120 is configured to output a clock signal which is distributed to each of the PHYs in the second portion 115b of the memory interface 115 via exemplary clock routing 1125 shown in FIG. 11. Each of the PHYs may use the clock signal provided by the second clock circuit 1120 to time the transmission of respective data bits, command bits, and/or address bits to the memory device 120. Each of the PHYs may also transmit the clock signal provided by the second clock circuit 1120 and/or transmit a clock signal based on the clock signal provided by the second clock circuit 1120 to the memory device 120.

FIG. 12 shows an example implementation of the first clock circuit 1110 according to certain aspects of the present disclosure. The second clock circuit 1120 may also be implemented with the exemplary implementation shown in FIG. 12. FIG. 12 also shows an exemplary implementation of the first PHY 710a and the second PHY 710b according to certain aspects. The first PHY 710a and the second PHY 710b are arranged side by side and may be used to implement each pair of side-by-side PHYs shown in FIGS. 11.

In this example, the clock circuit 1110 includes a first PLL 1210, a second PLL 1220, and a multiplexer 1230. The first PLL 1210 is configured to generate a first clock signal and the second PLL 1220 is configured to generate a second clock signal, which may have a different frequency than the first clock signal. The multiplexer 1230 has a first input 1232 coupled to the first PLL 1210 to receive the first clock signal, a second input 1234 coupled to the second PLL 1220 to receive the second clock signal, and an output 1236 coupled to the clock routing 1115. The multiplexer 1230 is configured to select the first clock signal or the second clock signal (e.g., based on a select signal from the memory controller 118 or another circuit), and output the selected clock signal to the clock routing 1115, which may distribute the selected clock signal to each of the PHYs in the first portion 115a of the memory interface 115.

In the example shown in FIG. 12, the first PHY 710a includes the first IO circuit 715a and the second IO circuit 720a discussed above. In this example, the first and second IO circuits 715a and 720a are coupled to the clock routing 1115 to receive the selected clock signal from the first clock circuit 1110. The first and second IO circuits 715a and 720a may use the selected clock signal to time the transmission of data bits, command bits, and/or address bits to the memory device 120. The first and second IO circuits 715a and 720a may also transmit the selected clock signal and/or transmit a clock signal based on the selected clock signal to the memory device 120 (e.g., to time the capture of data bits, command bits, and/or address bits at the memory device 120).

In the example shown in FIG. 12, the second PHY 710b includes the first IO circuit 715b and the second IO circuit 720b discussed above. In this example, the first and second IO circuits 715b and 720b are coupled to the clock routing 1115 to receive the selected clock signal from the first clock circuit 1110. The first and second IO circuits 715b and 720b may use the selected clock signal to time the transmission of data bits, command bits, and/or address bits to the memory device 120. The first and second IO circuits 715b and 720b may also transmit the selected clock signal and/or transmit a clock signal based on the selected clock signal to the memory device 120 (e.g., to time the capture of data bits, command bits, and/or address bits at the memory device 120).

FIG. 13A shows an example of the first IO circuit 715a according to certain aspects. In this example, the first IO circuit 715a includes a set of receivers 1320 configured to receive data from the memory device 120. For example, the set of receivers 1320 may include at least eight receivers (labeled “DQ_RX0” to “DQ_RX7”) configured to receive at least eight data bits in parallel from the memory device 120, where each of the receivers may be configured to receive a respective data bit from the memory device 120. The receivers may be coupled to the package 130 via respective signal bumps (e.g., exemplary signal bumps shown in any one of FIGS. 7B, 8B, and 9B) to receive the respective data bits. The set of receivers 1320 may be coupled to the memory controller 118 via signal routing (not shown) on the die 110.

In this example, the first IO circuit 715a also includes a first set of transmitters 1310 and a second set of transmitters 1315 configured to transmit data and a write clock signal to the memory device 120. The first set of transmitters 1310 includes transmitters (labeled “DQ_TX0” to “DQ_TX3”) where each of the transmitters may be configured to transmit a respective bit to the memory device 120. The second set of transmitters 1315 includes transmitters (labeled “DQ_TX4” to “DQ_TX7”) where each of the transmitters may be configured to transmit a respective data bit to the memory device 120. Together, the transmitters in the first and second sets of transmitters 1310 and 1315 may include at least eight transmitters to transmit at least eight data bits in parallel.

The second set of transmitters 1315 may also include a write clock transmitter (labeled “WCK_TX”) configured to generate the write clock signal WCK based on the clock signal received by the first IO circuit 715a (e.g., the selected clock signal from any of the exemplary PLLs discussed above), and transmit the write clock signal WCK to the memory device 120. The write clock signal WCK may be a single-ended clock signal or a differential clock signal. The transmitters in the first and second sets of transmitters 1310 and 1315 may time the transmissions of the respective bits based on the clock signal received by the first IO circuit 715a.

The transmitters in the first and second sets of transmitters 1310 and 1315 may be coupled to the package 130 via respective signal bumps (e.g., exemplary signal bumps shown in any one of FIGS. 7B, 8B, and 9B) to transmit the respective data bits. In certain aspects, the transmitters and the receivers may share signal bumps in which each of the shared signal bumps is coupled to a respective receiver and a respective transmitter. The transmitters in the first and second sets of transmitters 1310 and 1315 may be coupled to the memory controller 118 via signal routing (not shown) on the die 110.

In the example shown in FIG. 13A, the set of receivers 1320 is located between the first set of transmitters 1310 and the second set of transmitters 1315. The receivers in the set of receivers 1320 may be configured to receive a byte of data (e.g., eight data bits in parallel). Together, the transmitters in the first and second sets of transmitters 1310 and 1315 may be configured to transmit a byte of data (e.g., eight data bits in parallel). In this example, a first portion of the byte is transmitted by transmitters in the first set of transmitters 1310 and a second portion of the byte is transmitted by transmitters in the second set of transmitters 1315.

It is to be appreciated that the receivers are not limited to receiving a byte of data and the transmitters are not limited to transmitting a byte of data. For example, in other implementations, the set of receivers 1320 may include one or more additional receivers to receive twelve data bits in parallel, sixteen data bits in parallel, or another number of data bits in parallel, and the first and second sets of transmitters 1310 and 1315 may include one or more additional transmitters to transmit twelve data bits in parallel, sixteen data bits in parallel, or another number of data bits in parallel. Also, in some implementations, the set of receivers 1320 may also include an additional receiver for receiving a data masking bit from the memory device 120, and the first and second sets of transmitters 1310 and 1315 may include an additional transmitter for transmitting a data masking bit to the memory device 120 (e.g., for write data masking).

FIG. 13B shows an example of the second IO circuit 720a according to certain aspects. In this example, the second IO circuit 720a includes a set of receivers 1340 configured to receive data from the memory device 120. For example, the set of receivers 1340 may include at least eight receivers (labeled “DQ_RX0” to “DQ_RX7”) configured to receive at least eight data bits in parallel from the memory device 120, where each of the receivers may be configured to receive a respective data bit from the memory device 120. The receivers may be coupled to the package 130 via respective signal bumps (e.g., exemplary signal bumps shown in any one of FIGS. 7B, 8B, and 9B) to receive the respective data bits. The receivers may be coupled to the memory controller 118 via signal routing (not shown) on the die 110.

In this example, the second IO circuit 720a also includes a first set of transmitters 1330 and a second set of transmitters 1335 configured to transmit data and a write clock signal to the memory device 120. The first set of transmitters 1330 includes transmitters (labeled “DQ_TX0” to “DQ_TX3”) where each of the transmitters may be configured to transmit a respective data bit to the memory device 120. The second set of transmitters 1335 includes transmitters (labeled “DQ_TX4” to “DQ_TX7”) where each of the transmitters may be configured to transmit a respective data bit to the memory device 120. Together, the transmitters in the first and second sets of transmitters 1330 and 1335 may include at least eight transmitters to transmit at least eight data bits in parallel.

The second set of transmitters 1335 may also include a write clock transmitter (labeled “WCK_TX”) configured to generate the write clock signal WCK based on the clock signal received by the second IO circuit 720a (e.g., the selected clock signal from any of the exemplary PLLs discussed above), and transmit the write clock signal WCK to the memory device 120. The write clock signal WCK may be a single-ended clock signal or a differential clock signal. The transmitters in the first and second sets of transmitters 1330 and 1335 may time the transmissions of the respective data bits based on the clock signal received by the second IO circuit 720a.

The transmitters in the first and second sets of transmitters 1330 and 1335 may be coupled to the package 130 via respective signal bumps (e.g., exemplary signal bumps shown in any one of FIGS. 7B, 8B, and 9B) to transmit the respective data bits. In certain aspects, the transmitters and the receivers may share signal bumps in which each of the shared signal bumps is coupled to a respective receiver and a respective transmitter. The transmitters in the first and second sets of transmitters 1330 and 1335 may be coupled to the memory controller 118 via signal routing (not shown) on the die 110.

In the example shown in FIG. 13B, the set of receivers 1340 is located between the first set of transmitters 1330 and the second set of transmitters 1335. The receivers in the set of receivers 1340 may be configured to receive a byte of data (e.g., eight data bits in parallel). Together, the transmitters in the first and second sets of transmitters 1330 and 1335 may be configured to transmit a byte of data (e.g., eight data bits in parallel). In this example, a first portion of the byte is transmitted by transmitters in the first set of transmitters 1330 and a second portion of the byte is transmitted by transmitters in the second set of transmitters 1335. It is to be appreciated that the receivers are not limited to receiving a byte of data and the transmitters are not limited to transmitting a byte of data.

In this example, the second IO circuit 720a may also include a set of transmitters 1350 for transmitting command and address signals to the memory device 120. The transmitters in the set of transmitters 1350 may be coupled to the package 130 via respective signal bumps (e.g., exemplary signal bumps shown in any one of FIGS. 7B, 8B, and 9B) to transmit respective command and address bits. The transmitters in the set of transmitters 1350 may be coupled to the memory controller 118 via signal routing (not shown) on the die 110.

It is to be appreciated that the receivers are not limited to receiving a byte of data and the transmitters are not limited to transmitting a byte of data. For example, in other implementations, the set of receivers 1340 may include one or more additional receivers to receive twelve data bits in parallel, sixteen data bits in parallel, or another number of data bits in parallel, and the first and second sets of transmitters 1330 and 1335 may include one or more additional transmitters to transmit twelve data bits in parallel, sixteen data bits in parallel, or another number of data bits in parallel. Also, in some implementations, the set of receivers 1340 may also include an additional receiver for receiving a data masking bit from the memory device 120, and the first and second sets of transmitters 1330 and 1335 may include an additional transmitter for transmitting a data masking bit to the memory device 120 (e.g., for write data masking).

It is also to be appreciated that the transmitters for the command and address signal may be located in the first IO circuit 715a in other implementations, or the transmitters for the command and address signals may be split between the first IO circuit 715a and the second IO circuit 720a in other implementations.

It is to be appreciated that the receivers and the transmitters in the first IO circuit 715a are not limited to the exemplary arrangement (i.e., floorplan) shown in FIG. 13A. In this regard, FIG. 14A shows an example in which the first IO circuit 715a includes a set of transmitters 1410 arranged in a column, in which the set of transmitters 1410 includes the transmitters in the first and second sets of transmitters 1310 and 1315 shown in FIG. 13A. Also, in this example, the receivers in the set of receivers 1320 are also arranged in a column, in which each of the receivers in the set of receivers 1320 may be placed side-by-side with a respective one of the transmitters in the set of transmitters 1410. However, it is to be appreciated that the present disclosure is not limited to this example. It is to be appreciated that transmitters or receivers arranged in a column may also be described as being arranged in a row depending on the orientation in which the first IO circuit 715a is viewed.

It is to be appreciated that the receivers and the transmitters in the second IO circuit 720a are not limited to the exemplary arrangement (i.e., floorplan) shown in FIG. 13B. In this regard, FIG. 14B shows an example in which the second IO circuit 720a includes a set of transmitters 1420 arranged in a column, in which the set of transmitters 1420 includes the transmitters in the first and second sets of transmitters 1330 and 1335 shown in FIG. 13B. Also, in this example, the receivers in the set of receivers 1340 are also arranged in a column, in which each of the receivers in the set of receivers 1340 may be placed side-by-side with a respective one of the transmitters in the set of transmitters 1420. However, it is to be appreciated that the present disclosure is not limited to this example. Implementation examples are described in the following numbered clauses:

1. A system, comprising:
a die comprising:
a first set of physical layer (PHY) blocks arranged in a first column, wherein the first column extends along a side of the die; and
a second set of PHY blocks arranged in a second column adjacent to the first column, wherein the first set of PHY blocks include a first PHY block, the second set of PHY blocks include a second PHY block, and the first PHY block and the second PHY block share one or more clock resources.

2. The system of clause 1, wherein the one or more clock resources comprise:
a first locked loop (PLL) in the first PHY block, wherein the first PLL is configured to generate a first clock signal; and
a second PLL in the second PHY block, wherein the second PLL is configured to generate a second clock signal having a different frequency than the first clock signal.

3. The system of clause 2, wherein the first PHY block comprises:
a first input-output (IO) circuit;
a second IO circuit; and
a first multiplexer having a first input coupled to the first PLL, a second input coupled to the second PLL, and an output coupled to the first IO circuit and the second IO circuit.

4. The system of clause 3, wherein each of the first IO circuit and the second IO circuit includes at least eight transmitters configured to transmit at least eight bits in parallel.

5. The system of clause 4, wherein each of the first IO circuit and the second IO circuit includes at least eight receivers configured to receive at least eight bits in parallel.

6. The system of any one of clauses 3 to 5, wherein the second PHY block comprises: a third IO circuit;
a fourth IO circuit; and
a second multiplexer having a first input coupled to the first PLL, a second input coupled to the second PLL, and an output coupled to the third IO circuit and the fourth IO circuit.

7. The system of clause 2, wherein the first PHY block comprises:
a first input-output (IO) circuit;
a second IO circuit; and
a multiplexer having a first input coupled to the first PLL, a second input coupled to the second PLL, and an output coupled to the first IO circuit and the second IO circuit.

8. The system of clause 7, wherein the second PHY block comprises:
a third IO circuit; and
a fourth IO circuit, wherein the output of the multiplexer is coupled to the third IO circuit and the fourth IO circuit.

9. The system of clause 2, wherein the one or more clock resources comprise:
a first locked loop (PLL) configured to generate a first clock signal; and
a second PLL configured to generate a second clock signal having a different frequency than the first clock signal.

10. The system of clause 9, further comprising a multiplexer having a first input coupled to the first PLL, a second input coupled to the second PLL, and an output coupled to each PHY block in the first set of PHY blocks including the first PHY block and coupled to each PHY in the second set of PHY blocks including the second PHY block.

11. The system of clause 9 or 10, wherein the first PLL and the second PLL are located between a first portion of the first set of PHY blocks and a second portion of the first set of PHY blocks.

12. The system of any one of clauses 1 to 11, further comprising:
a package; and
bumps electrically coupling the first PHY block and the second PHY block to pins on the package.

13. The system of clause 12, wherein the bumps include one or more supply bumps overlapping the first PHY block and the second PHY block.

14. The system of clause 12 or 13, wherein the bumps include one or more ground bumps overlapping the first PHY block and the second PHY block.

15. The system of any one of clauses 12 to 14, further comprising:
a substrate, wherein the package is mounted on the substrate; and
a memory device mounted on the substrate, wherein the memory device is electrically coupled to the pins on the package.

16. The system of any one of clauses 1 to 15, wherein:
each of the first column and the second column extends in a first direction;
the first column has a first width in a second direction perpendicular to the first direction;
the second column has a second width in the second direction; and
a distance between the first column and the second column in the second direction is less than each of the first width and the second width.

17. A system, comprising:
a die including physical layer (PHY) blocks arranged in at least two columns, wherein a first column of the at least two columns extends along a side of the die, a second column of the at least two columns is adjacent to the first column, the PHY blocks include a first PHY block in the first column and a second PHY block in the second column, and the first PHY block and the second PHY block share one or more clock resources.

18. The system of clause 17, wherein the one or more clock resources comprise:
a first locked loop (PLL) in the first PHY block, wherein the first PLL is configured to generate a first clock signal; and
a second PLL in the second PHY block, wherein the second PLL is configured to generate a second clock signal having a different frequency than the first clock signal.

19. The system of clause 18, wherein the first PHY block comprises:
a first input-output (IO) circuit;
a second IO circuit; and
a first multiplexer having a first input coupled to the first PLL, a second input coupled to the second PLL, and an output coupled to the first IO circuit and the second IO circuit.

20. The system of clause 19, wherein each of the first IO circuit and the second IO circuit includes at least eight transmitters configured to transmit at least eight bits in parallel.

21. The system of clause 20, wherein each of the first IO circuit and the second IO circuit includes at least eight receivers configured to receive at least eight bits in parallel.

22. The system of any one of clauses 19 to 21, wherein the second PHY block comprises:
a third IO circuit;
a fourth IO circuit; and
a second multiplexer having a first input coupled to the first PLL, a second input coupled to the second PLL, and an output coupled to the third IO circuit and the fourth IO circuit.

23. The system of clause 18, wherein the first PHY block comprises:
a first input-output (IO) circuit;
a second IO circuit; and
a multiplexer having a first input coupled to the first PLL, a second input coupled to the second PLL, and an output coupled to the first IO circuit and the second IO circuit.

24. The system of clause 23, wherein the second PHY block comprises:
a third IO circuit; and
a fourth IO circuit, wherein the output of the multiplexer is coupled to the third
IO circuit and the fourth IO circuit.

25. The system of clause 17, further comprising:
a package; and
bumps electrically coupling the first PHY block and the second PHY block to pins on the package.

26. The system of clause 25, wherein the bumps include one or more supply bumps overlapping the first PHY block and the second PHY block.

27. The system of clause 25 or 26, wherein the bumps include one or more ground bumps overlapping the first PHY block and the second PHY block.

28. The system of any one of clauses 25 to 27, further comprising:
a substrate, wherein the package is mounted on the substrate; and
a memory device mounted on the substrate, wherein the memory device is electrically coupled to the pins on the package.

29. The system of any one of clauses 17 to 28, wherein:
each of the first column and the second column extends in a first direction;
the first column has a first width in a second direction perpendicular to the first direction;
the second column has a second width in the second direction; and
a distance between the first column and the second column in the second direction is less than each of the first width and the second width.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element. Further, it is to be appreciated that elements are not limited to the numerical designations used above to describe aspects of the present disclosure. For example, the first IO circuit 715b and the second IO circuit 720b in the second PHY 710b may also be referred to as the third IO circuit and the fourth IO circuit, respectively, to distinguish these IO circuits from the first IO circuit 715a and the second IO circuit 720a in the first PHY 710a.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” as used herein means electrically coupled and may refer to the direct or indirect electrical coupling between two structures. It is also to be appreciated that the term “ground” may refer to a DC ground or an AC ground, and thus the term “ground” covers both possibilities. As used herein, “approximately” means within 90 percent to 110 percent of the stated value.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A system, comprising:
a die comprising:
a first set of physical layer (PHY) blocks arranged in a first column, wherein the first column extends along a side of the die; and
a second set of PHY blocks arranged in a second column adjacent to the first column, wherein the first set of PHY blocks include a first PHY block, the second set of PHY blocks include a second PHY block, and the first PHY block and the second PHY block share one or more clock resources.

2. The system of claim 1, wherein the one or more clock resources comprise:
a first locked loop (PLL) in the first PHY block, wherein the first PLL is configured to generate a first clock signal; and
a second PLL in the second PHY block, wherein the second PLL is configured to generate a second clock signal having a different frequency than the first clock signal.

3. The system of claim 2, wherein the first PHY block comprises:
a first input-output (IO) circuit;
a second IO circuit; and
a first multiplexer having a first input coupled to the first PLL, a second input coupled to the second PLL, and an output coupled to the first IO circuit and the second IO circuit.

4. The system of claim 3, wherein each of the first IO circuit and the second IO circuit includes at least eight transmitters configured to transmit at least eight bits in parallel.

5. The system of claim 4, wherein each of the first IO circuit and the second IO circuit includes at least eight receivers configured to receive at least eight bits in parallel.

6. The system of claim 3, wherein the second PHY block comprises:
a third IO circuit;
a fourth IO circuit; and
a second multiplexer having a first input coupled to the first PLL, a second input coupled to the second PLL, and an output coupled to the third IO circuit and the fourth IO circuit.

7. The system of claim 2, wherein the first PHY block comprises:
a first input-output (IO) circuit;
a second IO circuit; and
a multiplexer having a first input coupled to the first PLL, a second input coupled to the second PLL, and an output coupled to the first IO circuit and the second IO circuit.

8. The system of claim 7, wherein the second PHY block comprises:
a third IO circuit; and
a fourth IO circuit, wherein the output of the multiplexer is coupled to the third IO circuit and the fourth IO circuit.

9. The system of claim 1, wherein the one or more clock resources comprise:
a first locked loop (PLL) configured to generate a first clock signal; and
a second PLL configured to generate a second clock signal having a different frequency than the first clock signal.

10. The system of claim 9, further comprising a multiplexer having a first input coupled to the first PLL, a second input coupled to the second PLL, and an output coupled to each PHY block in the first set of PHY blocks including the first PHY block and coupled to each PHY in the second set of PHY blocks including the second PHY block.

11. The system of claim 9, wherein the first PLL and the second PLL are located between a first portion of the first set of PHY blocks and a second portion of the first set of PHY blocks.

12. The system of claim 1, further comprising:
a package; and
bumps electrically coupling the first PHY block and the second PHY block to pins on the package.

13. The system of claim 12, wherein the bumps include one or more supply bumps overlapping the first PHY block and the second PHY block.

14. The system of claim 12, wherein the bumps include one or more ground bumps overlapping the first PHY block and the second PHY block.

15. The system of claim 12, further comprising:
a substrate, wherein the package is mounted on the substrate; and
a memory device mounted on the substrate, wherein the memory device is electrically coupled to the pins on the package.

16. The system of claim 1, wherein:
each of the first column and the second column extends in a first direction;
the first column has a first width in a second direction perpendicular to the first direction;
the second column has a second width in the second direction; and
a distance between the first column and the second column in the second direction is less than each of the first width and the second width.

17. A system, comprising:
a die including physical layer (PHY) blocks arranged in at least two columns, wherein a first column of the at least two columns extends along a side of the die, a second column of the at least two columns is adjacent to the first column, the PHY blocks include a first PHY block in the first column and a second PHY block in the second column, and the first PHY block and the second PHY block share one or more clock resources.
